(19) United States
(12) Patent Application Publication
(10) Pub. No.: US 2025/0366116 A1
(43) Pub. Date: Nov. 27, 2025

(54) SEMICONDUCTOR DEVICE

(71) Applicant: Mitsubishi Electric Corporation, Tokyo (JP)

(72) Inventors: Yumiko KOBAYASHI, Tokyo (JP); Tatsuro WATAHIKI, Tokyo (JP)

(73) Assignee: Mitsubishi Electric Corporation, Tokyo (JP)

(21) Appl. No.: 18/872,286

(22) PCT Filed: Jun. 28, 2022
(86) PCT No.: PCT/JP2022/025689

§ 371 Date: Dec. 6, 2024

(51) Int. Cl. H10D 62/60; H10D 30/47; H10D 62/10; H10D 62/824

(52) U.S. Cl. CPC H10D 62/60; H10D 30/475; H10D 62/102; H10D 62/824

(57) ABSTRACT

A semiconductor device includes, in this order: first to third channel layers made of a III-V group semiconductor containing Fe and C and a barrier layer made of a III-V group semiconductor having a wider bandgap than a bandgap of the third channel layer. A concentration profile satisfies below-mentioned conditions of: a) Fe concentration in the second channel layer and the third channel layer gradually decreases toward the barrier layer; b) a maximum value of the C concentration in the third channel layer is larger than an average value of the C concentration in the second channel layer; and c) the maximum value of the C concentration in the third channel layer is smaller than a maximum value of a sum of the Fe concentration and the C concentration in the first channel layer.

### TECHNICAL FIELD

The present disclosure relates to a semiconductor device, and particularly to a semiconductor device using a III-V group semiconductor.

### BACKGROUND ART

A III-V group semiconductor such as gallium nitride (GaN) is used for a semiconductor device such as a high electron mobility transistor (HEMT) for high frequency in some cases. Favorable pinch-off characteristics, that is to say, low leakage current between a source and a drain (also simply referred to as “leakage current” hereinafter) in a gate off state is required for the HEMT. Electrical resistance in a part where the leakage current may flow in an OFF state needs to be increased to suppress the leakage current.

Known for the above purpose is a technique of doping using iron (Fe) and carbon (C) as an acceptor for compensating for a residual donor of a semiconductor such as GaN. In the meanwhile, when electrons traveling in a channel are caught by a trap caused by this dopant, a phenomenon that drain current changes over time occurs in some cases, and this phenomenon is referred to as a current collapse. Thus, both suppression of the current collapse and acquisition of favorable pinch-off characteristics are not easily achieved. Considering this, devising a concentration profile of Fe and C in a thickness direction of a semiconductor layer is under investigation.

For example, Japanese Unexamined Patent Application Publication No. 2016-511545 (Patent Document 1) discloses a technique of a metal organic chemical vapor deposition (MOCVD) for forming a semi-insulative GaN layer doped with Fe and C.

Taken into consideration in the technique in the MOCVD are facts that Fe doping cannot be suddenly stopped, and that C doping can be suddenly stopped but the stopping is likely to cause crystal defect. Specifically, growth is performed with Fe doping at a concentration of approximately 5×10¹⁸/cm³ in the MOCVD. Subsequently, the intentional Fe doping is stopped, and the C doping is started; thus, growth with the C doping is started. Herein, in the MOCVD, the Fe concentration is not rapidly reduced but is gradually reduced with the growth even in the growth after the intentional Fe doping is stopped. The C doping is controlled so that the doping is started at a concentration of approximately 5×10¹⁶/cm³, which is then increased to approximately 5×10¹⁹/cm³, and stopped. Differing from the Fe doping, the C doping can be suddenly stopped.

### PRIOR ART DOCUMENTS

### Patent Document(s)

Patent Document 1: Japanese Unexamined Patent Application Publication No. 2016-511545

### SUMMARY

### Problem to be Solved by the Invention

According to the technique exemplified in the above publication, in the MOCVD, the growth with the Fe doping is firstly performed at the concentration of 5×10¹⁸/cm³ without the C doping. Only Fe is added as the dopant in the growth; thus, a total dopant concentration is 5×10¹⁸/cm³. Subsequently, the intentional Fe doping is stopped and the growth with the C doping is performed. The C concentration at the time of stopping the C doping is 5×10¹⁹/cm³. This final concentration 5×10¹⁹/cm³ of the C doping is higher than the initial total dopant concentration 5×10¹⁸/cm³ described above.

The present inventors have focused on a fact that when the concentration of the C doping is increased as described above, a recovery time constant, which is an index of a time required for recovering the electrons from the trapped state at a level formed by the C doping, increases. When the concentration profile described above is used, there is a problem that when the current collapse occurs by the trapping of the electrons, a time for the semiconductor device to recover original current characteristics, which is obtained when the electrons are released from the trap, increases due to the large recovery time constant described above.

The present disclosure is therefore has been made to solve such a problem, and it is an object to provide a semiconductor device which can, while an excessive recovery time constant is prevented, achieve both suppression of current collapse and acquisition of favorable pinch-off characteristics.

### Means to Solve the Problem

A semiconductor device according to the present disclosure includes, in this order in a thickness direction: a substrate; a first channel layer made of a III-V group semiconductor containing Fe and C as an impurity; a second channel layer made of a III-V group semiconductor containing Fe and C as an impurity; a third channel layer made of a III-V group semiconductor containing Fe and C as an impurity, and a barrier layer made of a III-V group semiconductor having a wider bandgap than a bandgap of the third channel layer. A semiconductor channel layer including the first channel layer, the second channel layer, and the third channel layer has a concentration profile on Fe concentration and C concentration depending on the thickness direction. The concentration profile satisfies below-mentioned conditions of: a) the Fe concentration in the second channel layer and the third channel layer gradually decreases toward the barrier layer; b) a maximum value of the C concentration in the third channel layer is larger than an average value of the C concentration in the second channel layer; and c) a maximum value of the C concentration in the third channel layer is smaller than a maximum value of a sum of the Fe concentration and the C concentration in the first channel layer.

### Effects of the Invention

According to the present disclosure, while an excessive recovery time constant is prevented, both suppression of current collapse and acquisition of favorable pinch-off characteristics can be achieved.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 A cross-sectional view schematically illustrating a configuration of a semiconductor device according to each of embodiments 1 to 3.

FIG. 2 A graph chart illustrating an example of a concentration profile on Fe concentration and C concentration depending on a thickness direction in a semiconductor channel layer included in the semiconductor device according to the embodiment 1.

FIG. 3 A graph chart exemplifying a calculation result of a relationship between C concentration in a third channel layer and a pinch-off voltage variation rate in the semiconductor device according to the embodiment 1.

FIG. 4 A graph chart exemplifying a calculation result of a relationship between a thickness of the third channel layer and current reduction rate after stress voltage application and a relationship between a thickness of the third channel layer and a pinch-off voltage variation rate in the semiconductor device according to the embodiment 1.

FIG. 5 A graph chart illustrating an example of a concentration profile on Fe concentration and C concentration depending on a thickness direction in a semiconductor channel layer included in the semiconductor device according to the embodiment 2.

FIG. 6 A graph chart illustrating an example of a concentration profile on Fe concentration and C concentration depending on a thickness direction in a semiconductor channel layer included in the semiconductor device according to a modification example of the embodiment 2.

FIG. 7 A graph chart illustrating an example of a concentration profile on Fe concentration and C concentration depending on a thickness direction in a semiconductor channel layer included in the semiconductor device according to the embodiment 3.

### DESCRIPTION OF EMBODIMENT(S)

An embodiment is described hereinafter using the diagrams. The same reference numerals are assigned to the same or a corresponding part in the diagrams hereinafter, and the repetitive description is omitted.

In the present specification, a III-V group semiconductor is a semiconductor in which at least one type of III group atom and at least one type of V group atom are used. In the present technical field, a III group is also referred to as a thirteenth group, and a V group is also referred to as a fifteenth group. The III group atom is aluminum (Al), gallium (Ga), and indium (In), for example. The V group atom is nitrogen (N), phosphorus (P), arsenic (As), and antimony (Sb), for example.

### Embodiment 1

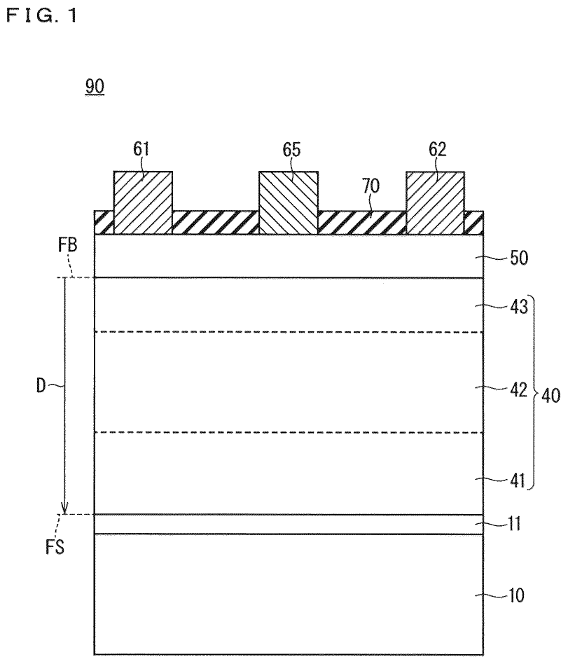

FIG. 1 is a cross-sectional view schematically illustrating a configuration of a semiconductor device 90 according to the present embodiment 1 (and embodiments 2 and 3 described hereinafter), As described in detail hereinafter, an impurity concentration profile is different between the embodiments 1 to 3. A semiconductor device 90 is a high electron mobility transistor (HEMT) using two dimensional electron gas (2DEG).

The semiconductor device 90 includes a substrate 10, a core formation layer 11, a semiconductor channel layer 40, and a barrier layer 50, in this order in a thickness direction (toward an upper side in FIG. 1). The semiconductor channel layer 40 includes a first channel layer 41, a second channel layer 42, and a third channel layer 43, in this order in a thickness direction (toward an upper side in FIG. 1). The semiconductor device 90 further includes a source electrode 61, a drain electrode 62, a gate electrode 65, and a protection layer 70. The source electrode 61, the drain electrode 62, and the gate electrode 65 are disposed on a semiconductor layer including the barrier layer 50 and the semiconductor channel layer 40, and may have contact with a surface (upper surface) of the barrier layer 50 as illustrated in FIG. 1. A part of the semiconductor layer having contact with the source electrode 61 and the drain electrode 62 (a part immediately below these electrodes in FIG. 1) may be a doped region to locally have a high impurity concentration to reduce contact resist with these electrodes.

The substrate 10 may be a single crystal substrate made of SiC, Si, sapphire, or GaN, and is an SiC single crystal substrate, for example. The core formation layer 11 may be made of a III-V group semiconductor, and is an AlN (aluminum nitride) layer, for example. A thickness of the core formation layer 11 is 10 nm, for example.

The semiconductor channel layer 40 (specifically, each of the first channel layer 41, the second channel layer 42, and the third channel layer 43) is made of a III-V group semiconductor containing Fe and C as an impurity, and this III-V group semiconductor is GaN, for example. Fe and C have a function as an acceptor. A thickness of the semiconductor channel layer 40 is equal to or larger than 300 nm and equal to or smaller than 1200 nm. A thickness of the third channel layer 43 is preferably equal to or larger than 20 nm and equal to or smaller than 400 nm, and is more preferably equal to or larger than 100 nm and equal to or smaller than 300 nm. The barrier layer 50 is made of a III-V group semiconductor having a wider bandgap than that of the third channel layer 43, and this III-V group semiconductor is AlGaN (aluminum gallium nitride), for example. A thickness of the barrier layer 50 is 20 nm, for example. The semiconductor channel layer 40 and the barrier layer 50 form a hetero junction. Electrons are accumulated by a polarization effect in an interface of the hetero junction; thus, 2DEG having a high concentration and high mobility is formed.

The semiconductor device 90 may include a spacer layer (not shown) between the semiconductor channel layer 40 and the barrier layer 50. The spacer layer is made of a III-V group semiconductor having a wider bandgap than that of the barrier layer 50, and this III-V group semiconductor is AlN, for example. A thickness of the spacer layer is equal to or larger than 0.5 nm and equal to or smaller than 3 nm. When the spacer layer is provided, alloy scattering can be reduced; thus, a mobility of the 2DEG can be improved. A conduction band offset gets large; thus, a density of the 2DEG can be increased, and gate leakage in a forward direction can be reduced.

The semiconductor device 90 may include a cap layer (not shown) between the barrier layer 50 and each of the source electrode 61, the gate electrode 65, and the drain electrode 62. The cap layer is made of a III-V group semiconductor such as GaN, for example. A thickness of the cap layer is 2 nm, for example. The protection layer 70 is an insulating layer provided for reducing a surface defect of the semiconductor layer located on an outermost surface (an uppermost side in FIG. 1), and is made of silicon nitride (SiN), for example.

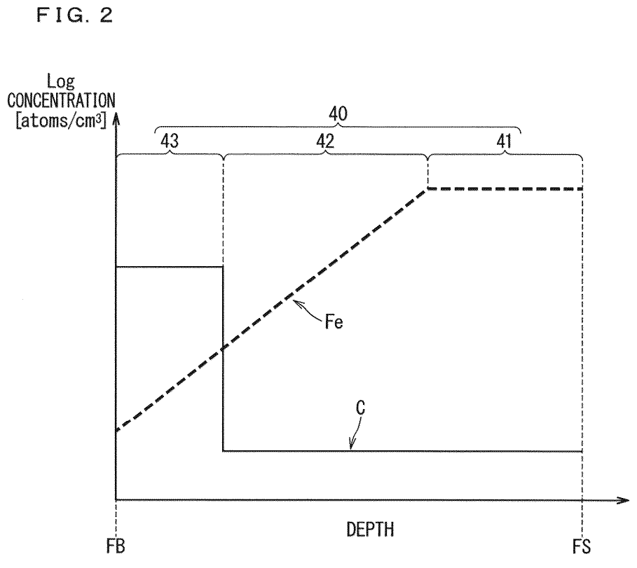

The semiconductor channel layer 40 has a concentration profile on the Fe concentration and the C concentration depending on the thickness direction. FIG. 2 is a graph chart illustrating an example of a concentration profile according to the present embodiment 1. “DEPTH” of a lateral axis of the graph corresponds to an arrow D (FIG. 1) from an upper surface FB (a surface facing the barrier layer 50) or the semiconductor channel layer 40 toward a lower surface FS (a surface facing the substrate 10) along the thickness direction.

The concentration profile (FIG. 2) satisfies below-mentioned conditions of:
a) the Fe concentration in the second channel layer 42 and the third channel layer 43 gradually decreases toward the barrier layer 50;
b) a maximum value of the C concentration in the third channel layer 43 is larger than an average value of the C concentration in the second channel layer 42; and
c) a maximum value of the C concentration in the third channel layer 43 is smaller than a maximum value of a sum of the Fe concentration and the C concentration in the first channel layer 41. “The maximum value of the sum of the Fe concentration and the C concentration in the first channel layer 41” described above indicates a maximum value in a profile of a total concentration of Fe and C in the first channel layer 41.

Details of the concentration profile in the present embodiment 1 are described hereinafter.

An acceptor concentration in the first channel layer 41 is sufficiently high; thus, conduction band energy increases, and a containment effect of the 2DEG is improved. Thus, the leakage current can be suppressed, and the pinch-off characteristics can be improved.

As described above, doping with Fe cannot be suddenly stopped under limitation of film deposition technique (typically, MOCVD) in the present technical field. Even when the intentional doping with Fe is stopped at a time when, after Fe doping has been purposefully performed in deposition of the first channel layer 41, the deposition of the first channel layer 41 is completed and deposition of the second channel 42 is started, the concentration of Fe which is actually doped does not rapidly decrease due to an upward diffusion of Fe, but gradually decreases in depositions of the second channel layer 42 and the third channel layer 43. Thus, Fe also remains in the second channel layer 42 and the third channel layer 43. Specifically, the Fe concentration in the second channel layer 42 and the third channel layer 43 gradually decreases from the first channel layer 41 toward the barrier layer 50 (in other words, toward the upper surface FB of the semiconductor channel layer 40).

In the meanwhile, C (carbon) is mixed from atmosphere in a manufacture process, thus is unintentionally doped to some extent. Thus, all of the first channel layer 41, the second channel layer 42, and the third channel layer 43 have at least a slight C concentration. The C concentration by this unintentional doping is relatively low, approximately equal to or lower than 3×10¹⁶ atoms/cm³. When this low concentration is ignored, it can be considered that the doping with C can be suddenly stopped, differing from the doping with Fe. Thus, the concentration can be purposefully and sharply changed in the depth direction in FIG. 2. Herein, a main level formed by the C doping is deepened when the C concentration is high, and this causes increase of a recovery time constant. Thus, in the first channel layer 41, it is preferable that not C but Fe is mainly doped at a high concentration to suppress the leakage current.

From the above viewpoint, the maximum value of the Fe concentration in the first channel layer 41 is preferably larger than that of the C concentration in the first channel layer 41. The maximum value of the Fe concentration in the first channel layer 41 is preferably equal to or larger than 1×10¹⁷ atoms/cm³ and equal to or smaller than 1×10¹⁹ atoms/cm³. When the Fe concentration is lower than that in this range, an effect of preventing the leakage current decreases. When the Fe concentration is higher than that in this range, the Fe concentration in the second channel layer 42 also unintentionally and unnecessarily increases by the above reason, and as a result, the current collapse is deteriorated in some cases. In the concentration profile exemplified in FIG. 2, the Fe concentration is higher than the C concentration at any depth position (in other words, any thickness position) in the first channel layer 41.

The concentration of Fe and C included in the second channel layer 42, in other words, the acceptor concentration is preferably as low as possible. This is because, when the concentration of the acceptor included in the second channel layer 42 is high, a trap density increases, and thus the current collapse may be deteriorated in some cases. In the meanwhile, the Fe concentration of the first channel layer 41 is relatively high as described above, and as a result, it is difficult to reduce the Fe concentration of the second channel layer 42 by the reason described above. Thus, the maximum value of the Fe concentration in the second channel layer 42 is larger than the average value of the C concentration in the second channel layer 42. In the concentration profile exemplified in FIG. 2, the Fe concentration is higher than the C concentration at any depth position in the second channel layer 42. In the concentration profile exemplified in FIG. 2, a minimum value of the Fe concentration in the second channel layer 42 is larger than the maximum value of the C concentration also in the second channel layer 42. In the second channel layer, the average value of the C concentration is preferably equal to or smaller than 3×10¹⁶ atoms/cm³, and the maximum value of the C concentration is more preferably equal to or smaller than 3×10¹⁶ atoms/cm³.

The maximum value of the C concentration in the third channel layer is larger than the average value of the C concentration in the second channel layer 42. Accordingly, conduction band energy increases in a region near the 2DEG; thus, a containment effect of the 2DEG is improved. Thus, the leakage current is reduced, a drain induced barrier lowering (DIBL) effect in applying high drain voltage is also suppressed, and the pinch-off characteristics are improved. Furthermore, a conduction band barrier is increased; thus, trapping of the electrons in the 2DEG to a side of the second channel layer 42 can be suppressed. As described above, both suppression of the current collapse and acquisition of favorable pinch-off characteristics can be achieved. Thus, it is preferable that the C concentration is high in the third channel layer 43 while the C concentration is kept low in the second channel layer 42; thus, it is preferable that the C concentration has a step-like change as illustrated in FIG. 2 at the interface between the second channel layer 42 and the third channel layer 43.

Herein, when the C concentration in the third channel layer 43 increases, the trap density also increases. In the meanwhile, the trap level and a fermi level are close to each other near an electron traveling region; thus, the electrons have been already trapped in most of trap levels without stress voltage. Thus, change of an ionized trap density is small before and after the stress. Thus, increase of the C concentration to some extent hardly leads to deterioration of the current collapse. Thus, the maximum value of the C concentration is preferably large enough to suppress the leakage current. However, an excess C concentration forms an excessively deep trap level, and as a result, it leads to substantial deterioration of the current collapse and substantial increase of the recovery time constant. According to the review of the present inventors, in order to prevent the substantial deterioration of the current collapse and the substantial increase of the recovery time constant, the maximum value of the C concentration in the third channel layer 43 is preferably smaller than a maximum value of a sum of the Fe concentration and the C concentration in the first channel layer 41, and is more preferably half the sum thereof or less.

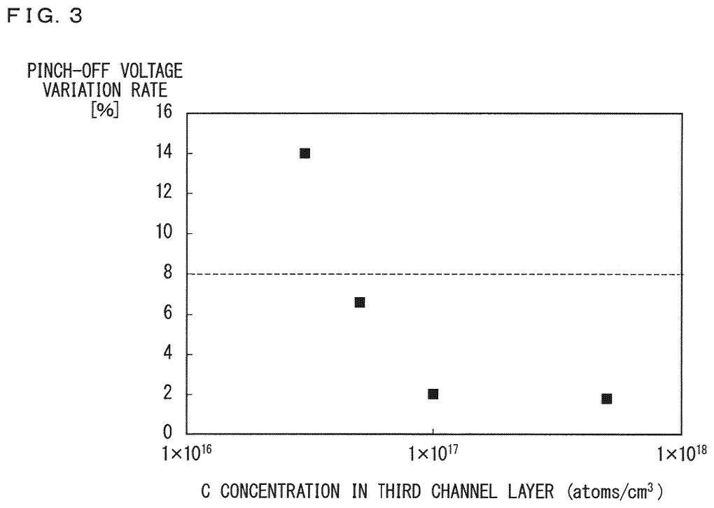

FIG. 3 is a graph chart exemplifying a calculation result of a relationship between the C concentration in the third channel layer and 43 a pinch-off voltage variation rate in a case where the drain voltage is changed from 5V to 50V in the semiconductor device 90 according to the present embodiment 1. When the drain voltage is increased, the pinch-off voltage is shifted to a negative direction due to the DIBL effect. A value obtained by dividing this shift amount by the pinch-off voltage in a case where the drain voltage is low is defined as the pinch-off voltage variation rate. Thus, the pinch-off voltage variation rate illustrated in FIG. 3 is a value obtained by dividing the shift amount of the pinch-off voltage in a case where the drain voltage is changed from 5V to 50V by the pinch-off voltage in a case where the drain voltage is 5V.

It is recognized from the graph in FIG. 3 that increase of the C concentration of the third channel layer 43 to some extent leads to improvement of the pinch-off characteristics. In a normal actual usage of the semiconductor device 90, the pinch-off voltage variation rate is preferably approximately 8% or less (refer to a broken line in FIG. 3), and in consideration of this condition, the maximum value of the C concentration of the third channel layer 43 is equal to or larger than 5×10¹⁶ atoms/cm³, and is more preferably equal to or larger than 1×10¹⁷ atoms/cm³. However, when the C concentration of the third channel layer 43 is excessive, the recovery time constant is excessive due to the condition where the depth of the main trap level derived from C increases as described above. From this viewpoint, the maximum value of the C concentration in the third channel layer 43 is preferably equal to or smaller than 5×10¹⁷ atoms/cm³.

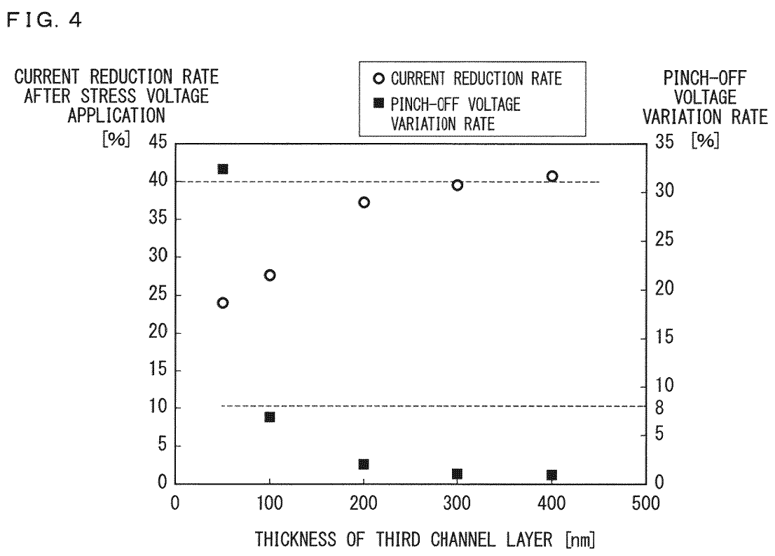

FIG. 4 is a graph chart exemplifying a calculation result of a relationship between the thickness of the third channel layer 43 and the current reduction rate after the stress voltage application and a relationship between the thickness of the third channel layer 43 and the pinch-off voltage variation rate in the semiconductor device 90 according to the present embodiment 1. Definition of the pinch-off voltage variation rate is the same as the case in FIG. 3.

It is recognized from the graph in FIG. 4 that increase of the thickness of the third channel layer 43 to some extent leads to improvement of the pinch-off characteristics. In the meanwhile, it is recognized that decrease of the thickness of the third channel layer 43 to some extent leads to suppression 7 of the current reduction rate after the stress voltage application, in other words, suppression of the current collapse. Accordingly, there is a trade-off relationship between the improvement of the pinch-off characteristics and the suppression of the current collapse with regard to the thickness of the third channel layer 43. Herein, as described above, the pinch-off voltage variation rate is preferably approximately 8% or less (refer to a broken line in a lower side in FIG. 4). The current reduction rate after the stress voltage application is preferably approximately 40% or less (refer to a broken line on an upper side in FIG. 4) in a normal actual usage of the semiconductor device 90. Thus, the thickness of the third channel layer 43 is preferably equal to or larger than 100 nm and equal to or smaller than 300 nm to achieve both the improvement of the pinch-off characteristics and the suppression of the current collapse. A most appropriate value of the thickness of the third channel layer 43 depends on the C concentration of the third channel layer 43 and the Fe concentration of the first channel layer 41.

According to the present embodiment 1 (refer to FIG. 2), the Fe concentration in the second channel layer 42 and the third channel layer 43 gradually decreases toward the barrier layer 50. Accordingly, the high Fe concentration of the first channel layer 41 can be ensured while the Fe concentration in the upper surface Fb of the semiconductor channel layer 40 is suppressed. Thus, Fe can be mainly used as the acceptor for ensuring the favorable pinch-off characteristics in the first channel layer 41. Thus, the C concentration needs not be high in the first channel layer 41. This contributes to prevention of the excessive recovery time constant.

Secondly, while the Fe concentration in the third channel layer 43 is low by gradual decrease of the Fe concentration as described above, the maximum value of the C concentration in the third channel layer 43 is larger than the average value of the C concentration in the second channel layer 42. The high C concentration in the third channel layer 43 improved is the effect of narrowly containing the two dimensional electron gas (2DEG) near the barrier layer 50. This effect contributes to both improvement of the pinch-off characteristics and reduction of the current collapse. The feature of the C concentration described above is that, in other words, the average value of the C concentration in the second channel layer 42 is smaller than the maximum value of the C concentration in the third channel layer 43. Accordingly, the acceptor concentration of the second channel layer 42 can be reduced. Thus, the current collapse due to the trapping of the electrons in the 2DEG in the second channel layer 42 can be suppressed.

Thirdly, the maximum value of the C concentration in the third channel layer 43 is smaller than the average value of the C concentration in the second channel layer 42 as described above, but is smaller than the maximum value of the sum of the Fe concentration and the C concentration in the first channel layer 41. Accordingly, the electrons which have spread from the 2DEG to the third channel layer 43 are prevented from spreading further to the first channel layer 41. This contributes to the favorable pinch-off characteristics.

According to the above configuration, while the excessive recovery time constant is prevented, both suppression of the current collapse and acquisition of the favorable pinch-off characteristics can be achieved.

The maximum value of the C concentration in the third channel layer 43 may be equal to or larger than 3×10¹⁶ atoms/cm³ and equal to or smaller than 5×10¹⁷ atoms/cm³. Accordingly, both suppression of the current collapse and acquisition of favorable pinch-off characteristics can be achieved more sufficiently.

The maximum value of the Fe concentration in the first channel layer 41 may be equal to or larger than 1×10¹⁷ atoms/cm³ and equal to or smaller than 1×10¹⁹ atoms/cm³. Accordingly, while the excessive recovery time constant is prevented, suppression of the current collapse and acquisition of the favorable pinch-off characteristics can be achieved more reliably.

The maximum value of the C concentration in the third channel layer 43 may be equal to or less than half the maximum value of the sum of the Fe concentration and the C concentration in the first channel layer 41. Accordingly, while the excessive recovery time constant is prevented, both suppression of the current collapse and acquisition of the favorable pinch-off characteristics can be achieved more reliably.

The maximum value of the Fe concentration in the second channel layer 42 may be larger than the average value of the C concentration in the second channel layer 42. Accordingly, while the excessive recovery time constant is prevented, both suppression of the current collapse and acquisition of the favorable pinch-off characteristics can be achieved more reliably.

The maximum value of the Fe concentration in the first channel layer 41 may be larger than the maximum value of the C concentration in the first channel layer 41. Accordingly, both suppression of the excessive recovery time constant and acquisition of the favorable pinch-off characteristics can be achieved more sufficiently.

The C concentration may have the step-like change at the interface between the second channel layer 42 and the third channel layer 43. Accordingly, both suppression of the current collapse and acquisition of the favorable pinch-off characteristics can be achieved more sufficiently.

The third channel layer 43 has the thickness equal to or larger than 100 nm and equal to or smaller than 300 nm. Accordingly, both suppression of the current collapse and acquisition of the favorable pinch-off characteristics can be achieved more sufficiently.

### Embodiment 2

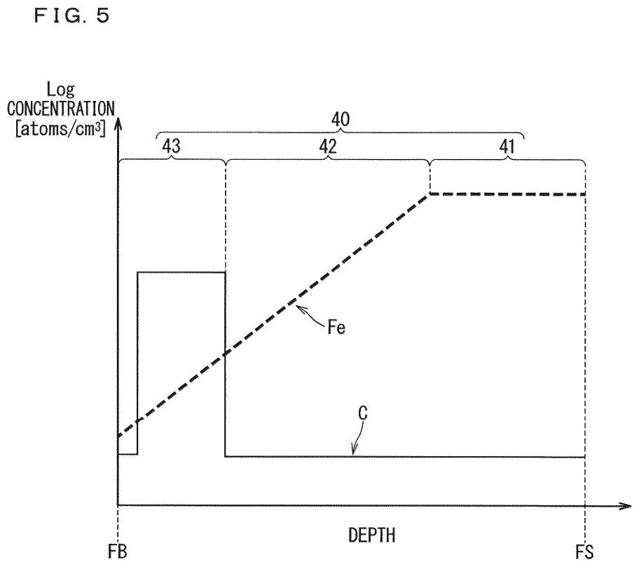

FIG. 5 is a graph chart illustrating an example of a concentration profile on the Fe concentration and the C concentration depending on the thickness direction in the semiconductor channel layer 40 included in the semiconductor device 90 (FIG. 1) according to the present embodiment 2. In the present embodiment, the C concentration at the interface between the third channel layer 43 and the layer including the barrier layer 50 on the third channel layer 43 is lower than that at the interface between the third channel layer 43 and the second channel layer 42, and is equal to or smaller than 3×10¹⁶ atoms/cm³. “The layer including the barrier layer 50 on the third channel layer 43” described above corresponds to the barrier layer 50 when the third channel layer 43 and the barrier layer 50 have directly contact with each other as illustrated in FIG. 1, and corresponds to a stacked body of the spacer layer and the barrier layer 50 when the space layer described above is provided between the third channel layer 43 and the barrier layer 50. When the condition described above is expressed by the other way, the C concentration in the upper surface FB of the semiconductor channel layer 40 is lower than that at the interface between the third channel layer 43 and the second channel layer 42, and is equal to or smaller than 3×10¹⁶ atoms/cm³.

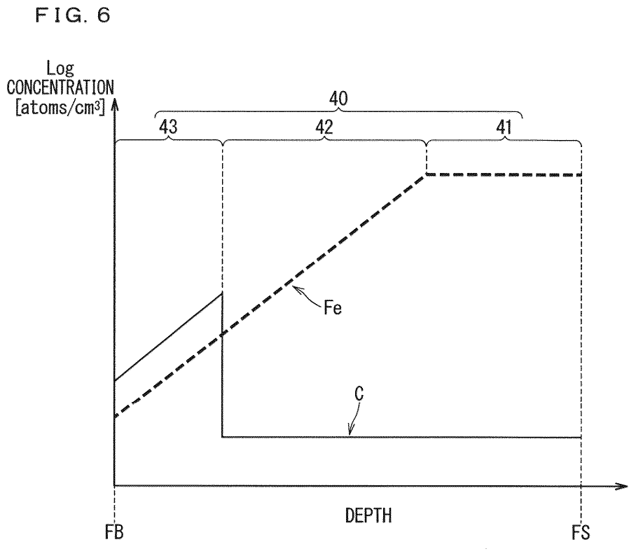

The C concentration needs to decrease toward the upper surface FB (in other words, the layer including the barrier layer 50 on the third channel layer 43) in at least a part of the third channel layer 43 to obtain the profile of the C concentration as described above. This decrease may be the step-like decrease as illustrated in FIG. 5, or may also be the gradual decrease as with the modification example illustrated in FIG. 6.

A configuration other than that describe above is substantially the same as that according to the embodiment 1 described above. Thus, also according to the present embodiment, while the excessive recovery time constant is prevented, both suppression of the current collapse and acquisition of the favorable pinch-off characteristics can be achieved.

When the impurity concentration in the electron traveling region is excessively high, mobility excessively decreases due to ionized impurity scattering. Particularly, when the acceptor concentration is excessively high, the density of the 2DEG also excessively decreases due to increase of the conduction band energy. When the concentration profile described above in the present embodiment is used, decrease of the mobility in the electron travel region can be suppressed, and decrease of the density of the 2DEG can also be suppressed. Accordingly, current characteristics in an ON state of the semiconductor device 90 can be enhanced.

### Embodiment 3

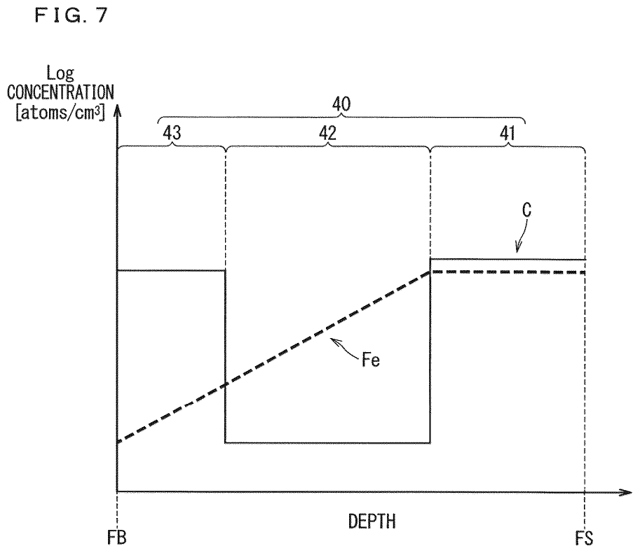

FIG. 7 is a graph chart illustrating an example of a concentration profile on the Fe concentration and the C concentration depending on the thickness direction in the semiconductor channel layer 40 included in the semiconductor device 90 (FIG. 1) according to the present embodiment 3.

In the present embodiment 3, the maximum value of the Fe concentration in the first channel layer 41 is smaller than that of the C concentration in the first channel layer 41. The maximum value of the Fe concentration in the first channel layer 41 is not so large; thus, the Fe concentration in the unintentional doping can be reduced in the second channel layer 42 and the third channel layer 43. Accordingly, the current collapse can be reduced.

While the maximum value of the Fe concentration in the first channel layer 41 is small as described above, in order to avoid a situation where the favorable pinch-off characteristics cannot be sufficiently obtained due to the small maximum value, it is sufficient that the acceptor concentration in the first channel layer 41 is ensured by increasing the maximum value of the C concentration in the first channel layer 41. However, this maximum value of the C concentration is preferably equal to or smaller than 5×10¹⁷ atoms/cm³ so that the level of the main trap formed due to the C doping is not excessively deep.

In the concentration profile exemplified in FIG. 7, the Fe concentration is lower than the C concentration at any depth position (in other words, any thickness position) in the first channel layer 41.

A configuration other than that described above in the present embodiment 3 is substantially the same as that according to the present embodiment 1; thus, the repetitive description is omitted.

Each embodiment can be arbitrarily combined, or each embodiment can be appropriately varied or omitted. Although the present disclosure is described in detail, the foregoing description is in all aspects illustrative and does not restrict the disclosure. It is therefore understood that numerous modifications not exemplified can be devised.

### EXPLANATION OF REFERENCE SIGNS

10 substrate, 11 core formation layer, 40 semiconductor channel layer, 41 first channel layer, 42 second channel layer, 43 third channel layer, 50 barrier layer, 61 source electrode, 62 drain electrode, 65 gate electrode, 70 protection layer, 90 semiconductor device.

1. A semiconductor device, comprising, in this order in a thickness direction:
a substrate;
a first channel layer made of a III-V group semiconductor containing Fe and C as an impurity;
a second channel layer made of a III-V group semiconductor containing Fe and C as an impurity;
a third channel layer made of a III-V group semiconductor containing Fe and C as an impurity; and
a barrier layer made of a III-V group semiconductor having a wider bandgap than a bandgap of the third channel layer, wherein
a semiconductor channel layer including the first channel layer, the second channel layer, and the third channel layer has a concentration profile on Fe concentration and C concentration depending on the thickness direction, and the concentration profile satisfies below-mentioned conditions of:
a) the Fe concentration in the second channel layer and the third channel layer gradually decreases toward the barrier layer;
b) a maximum value of the C concentration in the third channel layer is larger than an average value of the C concentration in the second channel layer; and
c) the maximum value of the C concentration in the third channel layer is smaller than a maximum value of a sum of the Fe concentration and the C concentration in the first channel layer; and
the maximum value of the C concentration in the third channel layer is equal to or larger than 5×10¹⁶ atoms/cm³, and equal to or smaller than 5×10¹⁷ atoms/cm³.

2. (canceled)

3. The semiconductor device according to claim 1, wherein
a maximum value of the Fe concentration in the first channel layer is equal to or larger than 1×10¹⁷ atoms/cm³, and equal to or smaller than 1×10¹⁹ atoms/cm³.

4. The semiconductor device according to claim 1, wherein
the maximum value of the C concentration in the third channel layer is equal to or less than half the maximum value of the sum of the Fe concentration and the C concentration in the first channel layer.

5. The semiconductor device according to claim 1, wherein
a maximum value of the Fe concentration in the second channel layer is larger than the average value of the C concentration in the second channel layer.

6. The semiconductor device according to claim 1, wherein
a maximum value of the Fe concentration in the first channel layer is larger than a maximum value of the C concentration in the first channel layer.

7. The semiconductor device according to claim 1, wherein
the C concentration has a step-like change at an interface between the second channel layer and the third channel layer.

8. The semiconductor device according to claim 1, wherein the third channel layer has a thickness equal to or larger than 100 nm and equal to or smaller than 300 nm.

9. The semiconductor device according to claim 1, wherein
the C concentration at an interface between the third channel layer and a layer including the barrier layer on the third channel layer is lower than the C concentration at the interface between the third channel layer and the second channel layer, and is equal to or smaller than 3×10¹⁶ atoms/cm³.
